(19) United States
(12) Patent Application Publication
(10) Pub. No.: US 2016/0155847 A1
(43) Pub. Date: Jun. 2, 2016

(54) THIN FILM TRANSISTOR AND ARRAY SUBSTRATE HAVING SAME

(71) Applicant: YE XIN TECHNOLOGY CONSULTING CO., LTD., Hsinchu (TW)

(72) Inventors: KUO-LUNG FANG, Hsinchu (TW); YI-CHUN KAO, Hsinchu (TW); CHIH-LUNG LEE, Hsinchu (TW); HSIN-HUA LIN, Hsinchu (TW); PO-LI SHIH, Hsinchu (TW)

(21) Appl. No.: 14/687,399

(22) Filed: Apr. 15, 2015

(30) Foreign Application Priority Data
Dec. 2, 2014 (TW) 103141714

(51) Int. Cl. H01L 29/786; H01L 27/12; H01L 29/06; H01L 29/423

(52) U.S. Cl. CPC H01L 29/7869; H01L 29/42384; H01L 27/1248; H01L 29/0653

(57) ABSTRACT

A thin film transistor includes a gate, a source, a drain, a channel layer, and a shielding layer. The shielding layer, the source, and the drain are located on a same layer. The shielding layer is located on the channel layer and is between the source and the drain to prevent light from being transmitted to the channel layer.

### CROSS-REFERENCE TO RELATED APPLICATIONS

This application claims priority to Taiwanese Patent Application No. 103141714 filed on Dec. 2, 2014 in the Taiwanese Intellectual Property Office, the contents of which are incorporated by reference herein.

### FIELD

Embodiments of the present disclosure generally relate to semiconductor components, and more particularly, to a thin film transistor and an array substrate having the thin film transistor.

### BACKGROUND

Metal oxide materials, such as indium zinc oxides (IZO) and indium gallium zinc oxides (IGZO) are widely used in thin film transistors (TFTs) to form a channel layer. The TFTs are widely used in electronic devices to serve as a switch component. When a voltage applied to a gate of the TFT exceeds a threshold voltage (Vth), the TFT can be turned on.

### BRIEF DESCRIPTION OF THE DRAWINGS

Implementations of the present technology will now be described, by way of example only, with reference to the attached figures.

FIG. 1 is an exploded view of a display panel having an array substrate.

FIG. 2 is a view of a pixel area of the array substrate of FIG. 1.

FIG. 3 is a cross-sectional view of the array substrate taken along line II-II of FIG. 2 according to a first embodiment.

FIG. 4 is a diagrammatic view of a shielding layer and a source and a drain of a thin film transistor located on the array substrate of FIG. 1 according to a second embodiment.

FIG. 5 is a cross-sectional view taken along line V-V of FIG. 4.

FIG. 6 is a diagrammatic view of the shielding layer and the source and the drain of the thin film transistor located on the array substrate of FIG. 1 according to a third embodiment.

FIG. 7 is a cross-sectional view taken along line VII-VII of FIG. 6.

FIG. 8 is a diagrammatic view of the shielding layer and the source and the drain of the thin film transistor located on the array substrate of FIG. 1 according to a fourth embodiment.

FIG. 9 is a cross-sectional view taken along line IX-IX of FIG. 8.

FIG. 10 is a partial view of a thin film transistor of FIG. 2 according to a fifth embodiment.

FIG. 11 is a diagrammatic view of the shielding layer and the source and the drain of the thin film transistor located on the array substrate of FIG. 1 according to a sixth embodiment.

FIG. 12 is a cross-sectional view taken along line XII-XII of FIG. 11.

FIG. 13 is a diagrammatic view of the shielding layer and the source and the drain of the thin film transistor located on the array substrate of FIG. 1 according to a seventh embodiment.

FIG. 14 is a cross-sectional view taken along line XIV-XIV of FIG. 13.

FIG. 15 is a partial view of a thin film transistor of FIG. 2 according to an eighth embodiment.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “coupled” is defined as connected, whether directly or indirectly through intervening components, and is not necessarily limited to physical connections. The connection can be such that the objects are permanently connected or releasably connected.

The present disclosure is described in relation to thin film transistor (TFT) which can be used in an array substrate of a display panel.

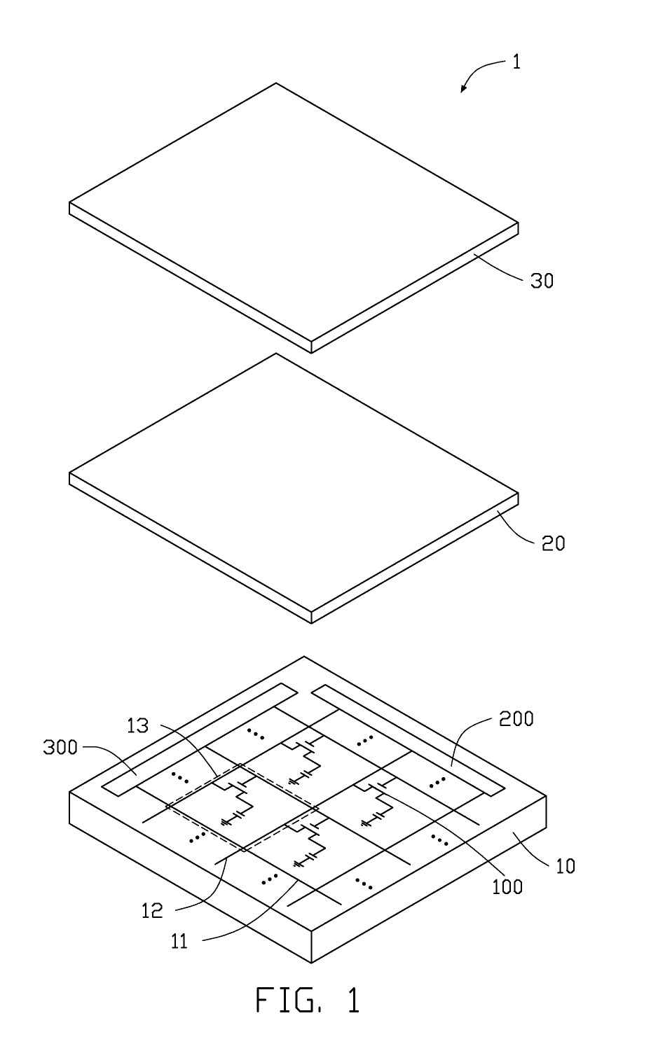

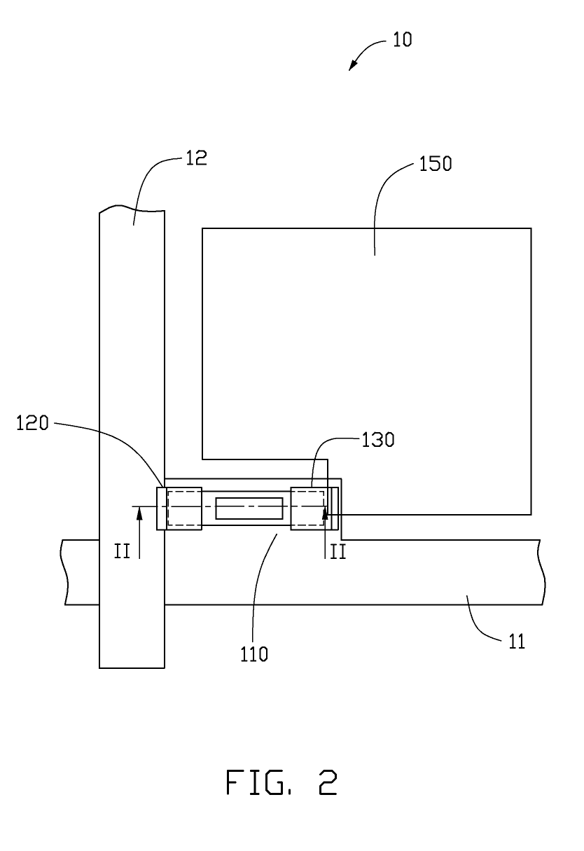

Referring to FIG. 1 and FIG. 2, FIG. 1 shows is an exploded view of a display panel 1 having an array substrate 10; FIG. 2 shows a view of a pixel area of the array substrate 10 of FIG. 1. The display panel 10 can further include a liquid crystal layer 20 and an opposite substrate 30 opposite to the array substrate 10. The array substrate 10 includes a plurality of gate lines 11 and a plurality of data lines. The data lines 12 are intersected with and insulated from the gate lines 11 to form a plurality of pixel units 13. In at least one embodiment, each pixel unit 13 is surrounded by two adjacent gate lines 11 and two adjacent data lines 12. Each pixel unit 13 can include at least one thin film transistor (TFT) 100 which is generally located at an intersection position of the gate line 11 and the data line 12. The TFT 100 includes a gate 110, a source 120, a drain 130, and a channel layer 103. The gate 110 is coupled to the gate line 11 to receive gate signals from a gate driver 300. The source 120 is coupled to the data line 12 to receive data signals from a data driver 200. The drain 130 is coupled to a pixel electrode 150 within the pixel unit 13.

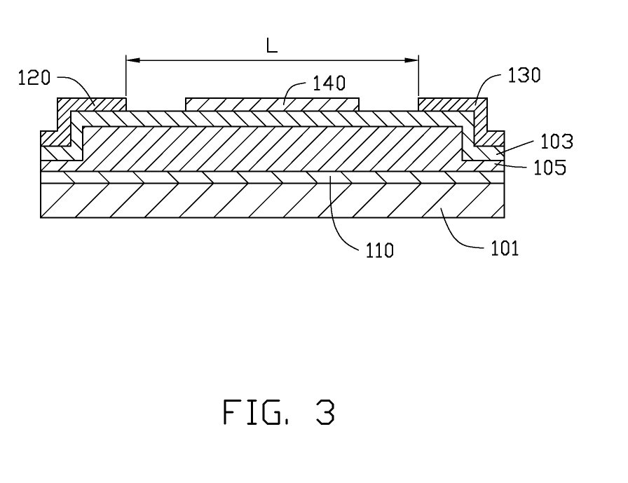

When a voltage of the gate signals output from the gate line 11 exceeds a threshold voltage (Vth) of the TFT 100, a channel layer 103 (shown in FIG. 3) of the TFT 100 will become a conductor to transmit the data signals from the source 120 to the drain 130. In at least one embodiment, the channel layer 103 can be made of materials having light sensitivity performance, such as metal oxide materials. Some non-limiting examples of the metal oxide materials are IGZO, ZnO, Ino, GaO.

Referring to FIG. 3, FIG. 3 is a cross-sectional view of the array substrate 10 taken along line II-II of FIG. 2 according to a first embodiment. The TFT 100 further includes a gate insulating layer 105 and a shielding layer 140. The gate 110 is formed on a substrate 101 and the gate insulating layer 103 is located on and covers the gate 110. The channel layer 103 is located on and covers the gate insulating layer 105, and the gate insulating layer 105 is thus sandwiched between the gate and the channel 103. The source 120, the drain 130, and the shielding layer 140 are located on a same layer. The shielding layer 140 is located right above the channel layer 103 and is between the source 120 and the drain 130, thereby blocking a portion of light from transmitting to the channel layer 103 to improve the stability of the TFT 100. In at least one embodiment, the shielding layer 140 is separated from the source 120 and the drain 130. A total distance of a first distance between the source 120 and the shielding layer 140 and a second distance between the drain 130 and the shielding layer 140 is less than a half of a distance “L” between the source 120 and the drain 130. That is, a length of the shield layer 140 is greater than a half of the distance “L” between the source 120 and the drain 130. The first distance between the source 120 and the shielding layer 140 can be equal to the second distance between the drain 130 and the shielding layer 140. The source 120 and the drain 130 can be “Z” shaped and are respectively located at two opposite ends of the channel 103. A length of the source 120 is substantially equal to a length of the drain 130.

In at least one embodiment, the shielding layer 140, the source 120, and the drain 130 can be made of the same materials in a same photo etching process (PEP). For example, a conductive layer can be deposited on the channel layer 103, and then the conductive layer can be patterned in the photo etching process using a photo mask to form the source 120, the drain 130, and the shielding layer 140. The conductive layer can be formed using metal materials or compound metal materials, such as molybdenum (Mo), aluminum (Al), chromium (Cr), copper (Cu), neodymium (Nd), or the compound materials thereof. In other embodiments, the conductive layer can be formed using non-metal conductive materials, such as transparent metal oxide materials. The conductive layer can be patterned to form the source 120, the drain 130, and the shielding layer 140 using a wet etching process.

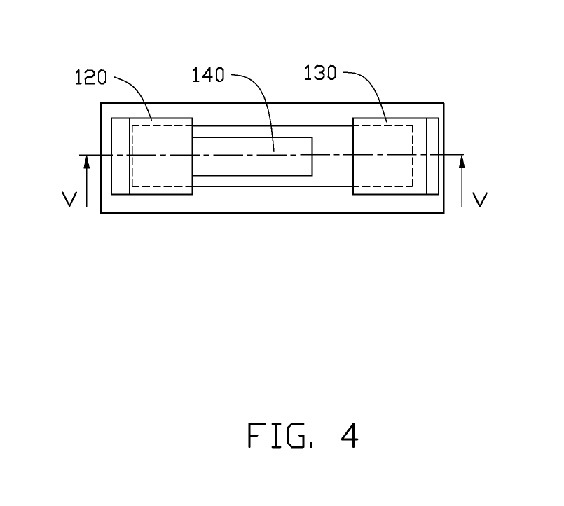

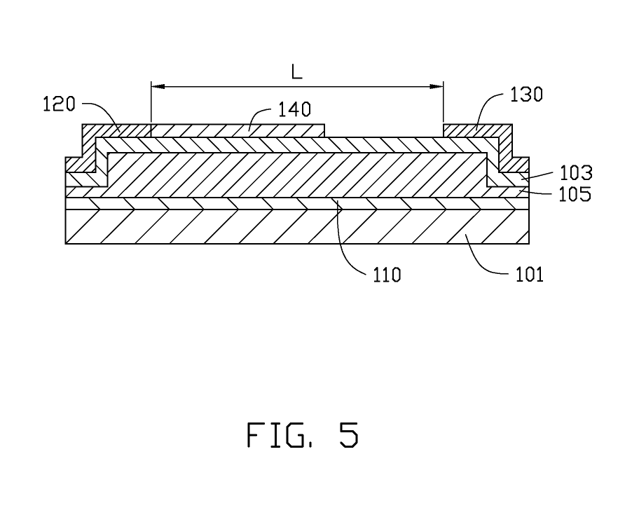

Referring to FIG. 4 and FIG. 5, FIG. 4 is a diagrammatic view of a shielding layer 140 and a source 120 and a drain 130 of a thin film transistor 100 located on the array substrate 10 of FIG. 1 according to a second embodiment, FIG. 5 is a cross-sectional view taken along line V-V of FIG. 4. In the second embodiment, the TFT 100 further includes a gate insulating layer 105 and a shielding layer 140. The gate 110 is formed on a substrate 101 and the gate insulating layer 103 is located on and covers the gate 110. The channel layer 103 is located on and covers the gate insulating layer 105, and the gate insulating layer 105 is thus sandwiched between the gate and the channel 103. The source 120, drain 130, and the shielding layer 140 are located on a same layer. The shielding layer 140 is located right above the channel layer 103 and is between the source 120 and the drain 130, thereby blocking a portion of light from transmitting to the channel layer 103 to improve the stability performance of the TFT 100. In at least one embodiment, the shielding layer 140 is coupled to the source 120 and is separated from the drain 130. A distance between the drain 130 and the shielding layer 140 is less than a half of a distance “L” between the source 120 and the drain 130. That is, a length of the shield layer 140 is greater than a half of the distance “L” between the source 120 and the drain 130. The source 120 and the drain 130 can be “Z” shaped and are respectively located at two opposite ends of the channel 103. A length of the source 120 is substantially equal to a length of the drain 130. The shielding layer 140 can be integrated with the source 120 and therefore the shielding layer 140 serves as a portion of the source 120.

It should be understood that the shielding layer 140 can be coupled to the drain 130 and be separated from the source 120. That is, the shielding layer 140 can be integrated with the drain 130 and therefore serve as a portion of the drain 130.

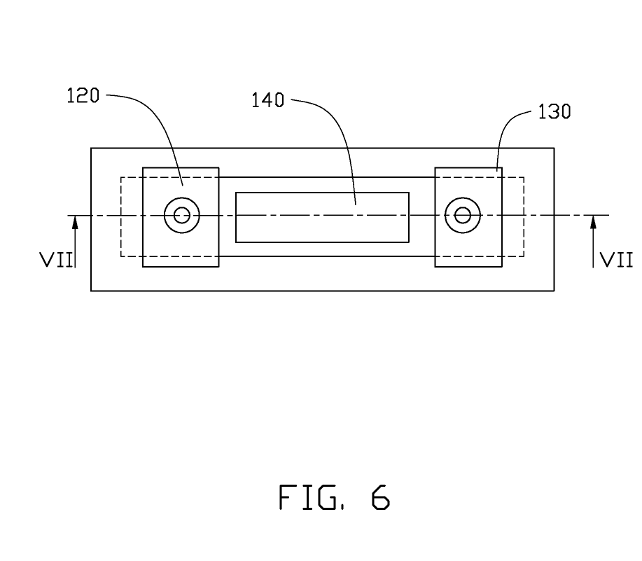

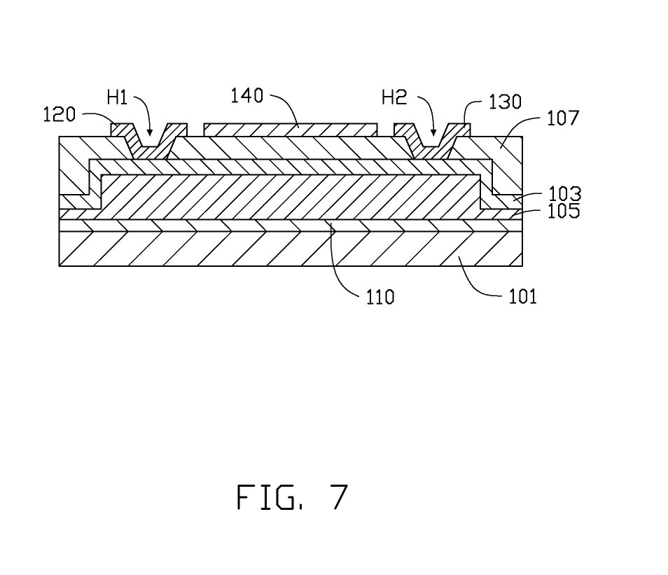

Referring FIG. 6 and FIG. 7, FIG. 6 is a diagrammatic view of a shielding layer 140 and a source 120 and a drain 130 of a thin film transistor 100 located on the array substrate 10 of FIG. 1 according to a third embodiment, FIG. 7 is a cross-sectional view taken along line VII-VII of FIG. 6.

In the third embodiment, the TFT 100 further includes a gate insulating layer 105 and a shielding layer 140. The gate 110 is formed on a substrate 101 and the gate insulating layer 103 is located on and covers the gate 110. The channel layer 103 is located on and covers the gate insulating layer 105, and the gate insulating layer 105 is thus sandwiched between the gate and the channel 103. The source 120, the drain 130, and the shielding layer 140 are located on a same layer. The shielding layer 140 is located between the source 120 and the drain 130. The TFT 100 further includes an etching stopping layer 107 located at a surface of the channel layer 103 adjacent to the source 120 and drain 130 to separate the source 120 from the drain 130. The etching stopping layer 107 can be made of transparent organic materials with light sensitivity performance. The etching stopping layer 107 is configured to prevent the channel layer 103 from being damaged in the etching process. A thickness of the etching stopping layer 107 is about one micrometer.

The etching stopping layer 107 defines two contact holes H1, H2 to expose a portion of the channel layer 103. The source 120 and the drain 130 are respectively filled into the two contact holes H1, H2 to contact with the channel layer 103. The two contact holes H1, H2 can be formed by etching the etching stopping layer 107 using a dry etching process, a plasma etching process, or a reactive ion etching (RIE) process. A distance between the two contact holes H1, H2 is about three micrometers to about five micrometers.

In at least one embodiment, the shielding layer 140 is located right above the etching stopping layer 107 and is between the source 120 and the drain 130. The shielding layer 140 is separated from the source 120 and the drain 130. A total distance of a first distance between the source 120 and the shielding layer 140 and a second distance between the drain 130 and the shielding layer 140 is less than a half of a distance between the source 120 and the drain 130. That is, a length of the shield layer 140 is greater than a half of the distance between the source 120 and the drain 130. The first distance between the source 120 and the shielding layer 140 can be equal to the second distance between the drain 130 and the shielding layer 140. A length of the source 120 is substantially equal to a length of the drain 130.

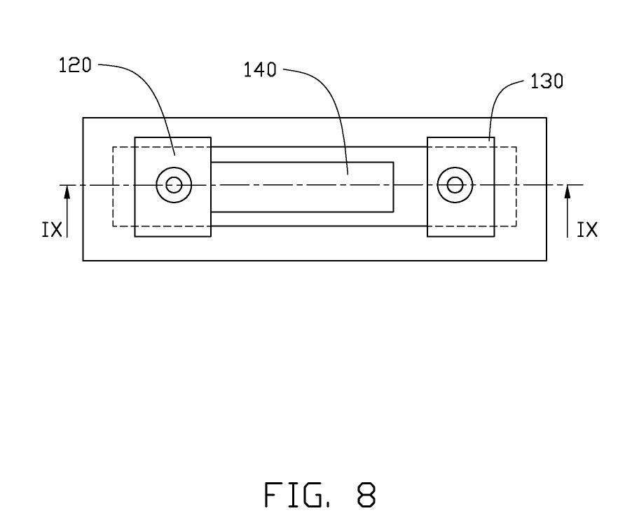

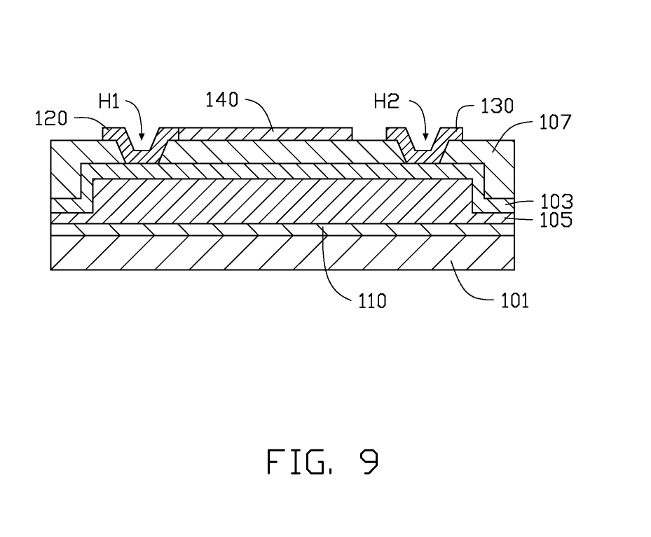

Referring to FIG. 8 and FIG. 9, FIG. 8 is a diagrammatic view of a shielding layer 140 and a source 120 and a drain 130 of the thin film transistor 100 located on the array substrate 10 according to a fourth embodiment, FIG. 9 is a cross-sectional view taken along line IX-IX of FIG. 8.

In the fourth embodiment, the TFT 100 further includes a gate insulating layer 105 and a shielding layer 140. The gate 110 is formed on a substrate 101 and the gate insulating layer 103 is located on and covers the gate 110. The channel layer 103 is located on and covers the gate insulating layer 105, and the gate insulating layer 105 is thus sandwiched between the gate and the channel 103. The source 120, the drain 130, and the shielding layer 140 are located on a same layer. The shielding layer 140 is located between the source 120 and the drain 130. The TFT 100 further includes an etching stopping layer 107 located at a surface of the channel layer 103 adjacent to the source 120 and drain 130 to separate the source 120 from the drain 130. The etching stopping layer 107 can be made of transparent organic materials with light sensitivity performance. The etching stopping layer 107 is configured to prevent the channel layer 103 from being damaged in the etching process. A thickness of the etching stopping layer 107 is about one micrometer.

The etching stopping layer 107 defines two contact holes H1, H2 to expose a portion of the channel layer 103. The source 120 and the drain 130 are respectively filled into the two contact holes H1, H2 to contact with the channel layer 103. The two contact holes H1, H2 can be formed by etching the etching stopping layer 107 using a dry etching process, a plasma etching process, or a reactive ion etching (RIE) process. A distance between the two contact holes H1, H2 is about three micrometers to about five micrometers.

In at least one embodiment, the shielding layer 140 is located right above the etching stopping layer 107 and is between the source 120 and the drain 130. The shield layer is coupled to the source 120 and is separated from the drain 130. A distance between the drain 130 and the shielding layer 140 is less than a half of a distance between the source 120 and the drain 130. That is, a length of the shield layer 140 is greater than a half of the distance between the source 120 and the drain 130. A length of the source 120 is substantially equal to a length of the drain 130. The shielding layer 140 can be integrated with the source 120 and therefore serve as a portion of the source 120.

It should be understood that, in other embodiments, the shielding layer 140 can be coupled to the drain 130 and be separated from the source 120. That is, the shielding layer 140 can be integrated with the drain 130 and therefore serve as a portion of the drain 130.

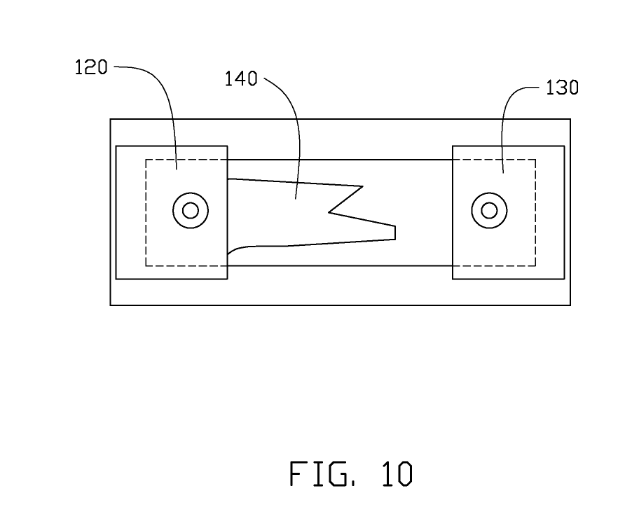

Referring to FIG. 10, FIG. 10 is a partial view of the thin film transistor 100 of FIG. 2 according to a fifth embodiment. The fifth embodiment is similar to the fourth embodiment except that the shielding layer 140 has an irregular structure at one end adjacent to the drain 130. In one non-limiting example, the irregular structure includes at least one concave portion towards the source and at least one protrusion portion protruding towards the drain. It is understood that, in other embodiments, the shielding layer 140 can be coupled to the drain 130 and be separated from the source 120. At this time, the irregular structure is located at one end of the shielding layer 140 adjacent to the source 120.

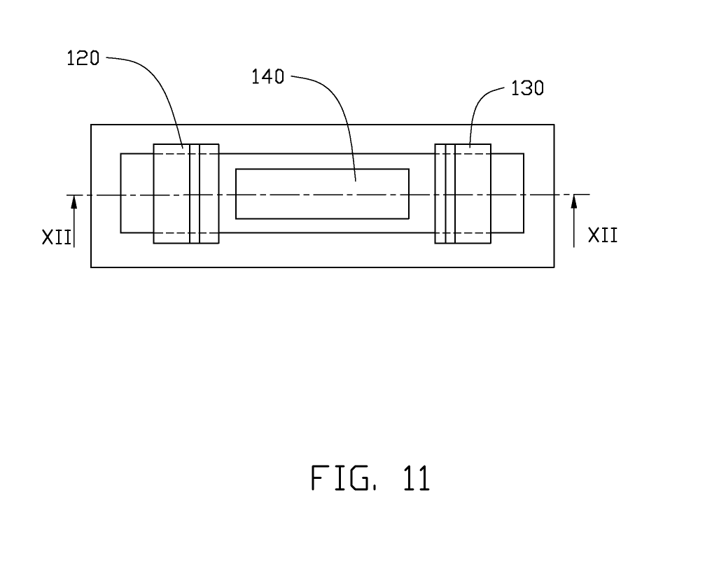

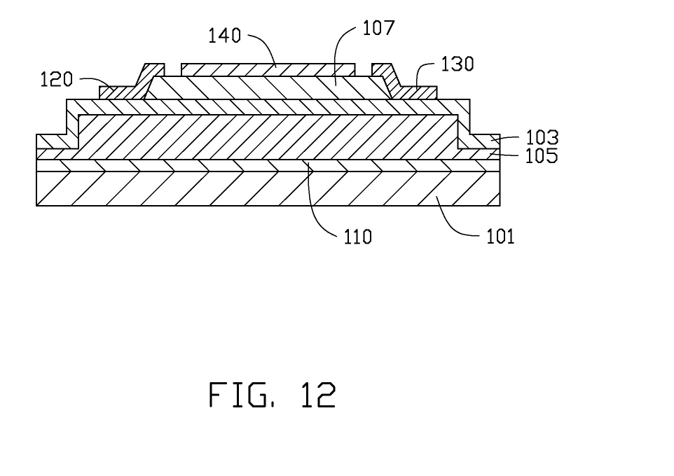

Referring to FIG. 11 and FIG. 12, FIG. 11 is a diagrammatic view of a shielding layer 140 and a source 120 and a drain 130 of the thin film transistor 100 located on the array substrate 10 of FIG. 1 according to a sixth embodiment, FIG. 12 is a cross-sectional view taken along line XII-XII of FIG. 11.

In the sixth embodiment, the TFT 100 further includes a gate insulating layer 105 and a shielding layer 140. The gate 110 is formed on a substrate 101 and the gate insulating layer 103 is located on and covers the gate 110. The channel layer 103 is located on and covers the gate insulating layer 105, and the gate insulating layer 105 is thus sandwiched between the gate and the channel 103. The source 120, the drain 130, and the shielding layer 140 are located on a same layer. The shielding layer 140 is located between the source 120 and the drain 130. The TFT 100 further includes an etching stopping layer 107 located at a surface of the channel layer 103 adjacent to the source 120 and drain 130 to separate the source 120 from the drain 130. The etching stopping layer 107 can be made of transparent organic materials with light sensitivity performance. The etching stopping layer 107 is configured to prevent the channel layer 103 from being damaged in the etching process. A thickness of the etching stopping layer 107 is about one micrometer.

A length of the etching stopping layer 107 is less than a length of the channel layer 103. The channel layer 103 is exposed out from two opposite sides of the etching stopping layer 107. The source 120 and the drain 130 are respectively located at the two opposite sides of the etching stopping layer 107 to contact with the channel layer 103. The shielding layer 140 is located right above the etching stopping layer 107 and is between the source 120 and the drain 130. The shielding layer 140 is separated from the source 120 and the drain 130. A total distance of a first distance between the source 120 and the shielding layer 140 and a second distance between the drain 130 and the shielding layer 140 is less than a half of a distance between the source 120 and the drain 130. That is, a length of the shield layer 140 is greater than a half of the distance between the source 120 and the drain 130. The first distance between the source 120 and the shielding layer 140 can be equal to the second distance between the drain 130 and the shielding layer 140. A length of the source 120 is substantially equal to a length of the drain 130.

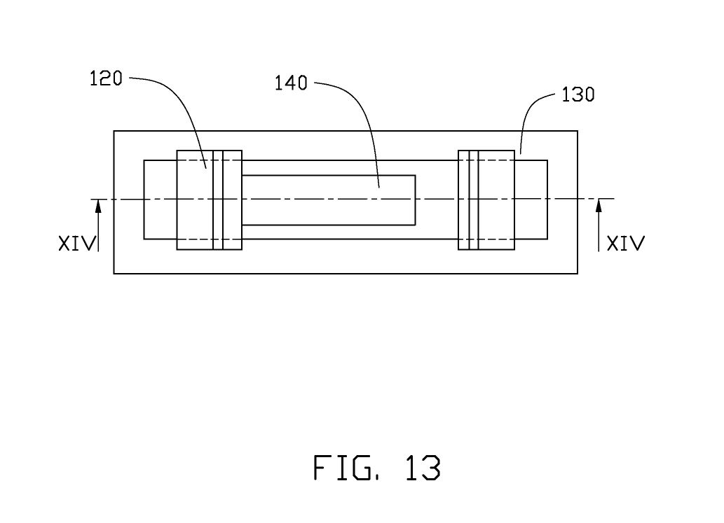

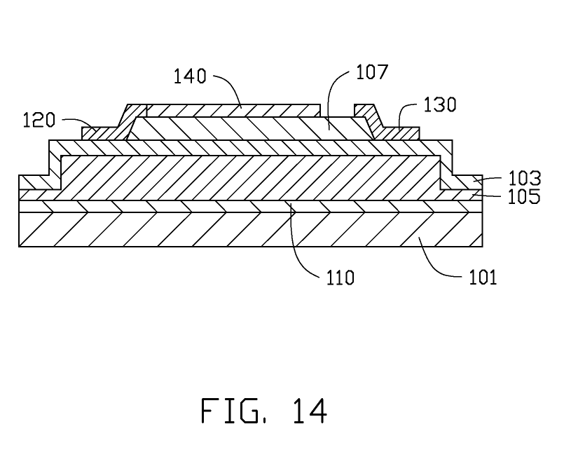

Referring to FIG. 13 and FIG. 14, FIG. 13 is a diagrammatic view of a shielding layer 140 and a source 120 and a drain 130 of the thin film transistor 100 located on the array substrate 10 of FIG. 1 according to a seventh embodiment, FIG. 14 is a cross-sectional view taken along line XIV-XIV of FIG. 13.

In the seventh embodiment, in the sixth embodiment, the TFT 100 further includes a gate insulating layer 105 and a shielding layer 140. The gate 110 is formed on a substrate 101 and the gate insulating layer 103 is located on and covers the gate 110. The channel layer 103 is located on and covers the gate insulating layer 105, and the gate insulating layer 105 is thus sandwiched between the gate and the channel 103. The source 120, the drain 130, and the shielding layer 140 are located on a same layer. The shielding layer 140 is located between the source 120 and the drain 130. The TFT 100 further includes an etching stopping layer 107 located at a surface of the channel layer 103 adjacent to the source 120 and drain 130 to separate the source 120 from the drain 130. The etching stopping layer 107 can be made of transparent organic materials with light sensitivity performance. The etching stopping layer 107 is configured to prevent the channel layer 103 from being damaged in the etching process. A thickness of the etching stopping layer 107 is about one micrometer.

A length of the etching stopping layer 107 is less than a length of the channel layer 103. That is, the etching stopping layer 107 is shorter than the channel layer 103. The channel layer 103 is exposed out from two opposite sides of the etching stopping layer 107. The source 120 and the drain 130 are respectively located at the two opposite sides of the etching stopping layer 107 to contact with the channel layer 103. The shielding layer 140 is located right above the etching stopping layer 107 and is between the source 120 and the drain 130. The shielding layer 140 is coupled to the source 120 and is separated from the drain 130. A distance between the drain 130 and the shielding layer 140 is less than a half of a distance between the source 120 and the drain 130. That is, a length of the shield layer 140 is greater than a half of the distance between the source 120 and the drain 130. A length of the source 120 is substantially equal to a length of the drain 130. The shielding layer 140 can be integrated with the source 120 and therefore serve as a portion of the source 120.

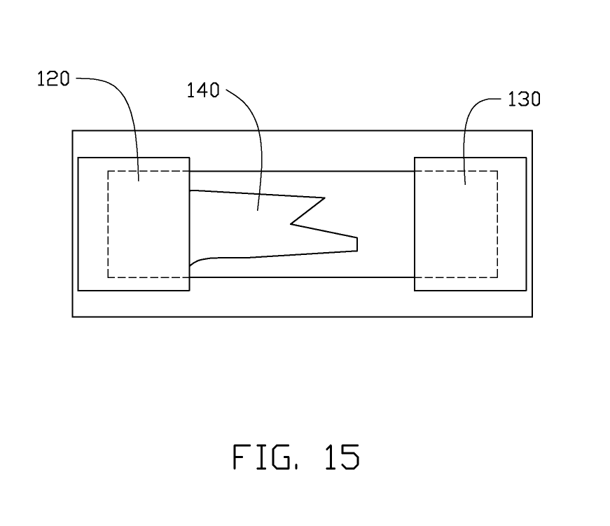

Referring to FIG. 15, FIG. 15 is a partial view of the thin film transistor 100 of FIG. 2 according to an eighth embodiment. The eighth embodiment is similar to the seventh embodiment except that the shielding layer 140 has an irregular structure at one end adjacent to the drain 130. In one non-limiting example, the irregular structure includes at least one concave portion towards the source and at least one protrusion portion protruding towards the drain. It is understood that, in other embodiments, the shielding layer 140 can be coupled to the drain 130 and be separated from the source 120. At this time, the irregular structure is located at one end of the shielding layer 140 adjacent to the source 120.

As described above, the TFT 100 of the present disclosure includes a shielding layer 140 located right above the channel layer 103 which is made from metal oxide materials. The shielding layer 140 can prevent a portion of the light from transmitting to the channel layer 103, and the stability of the TFT 100 is thus improved.

It should be understood that, in other embodiments, the shielding layer 140 can be coupled to the drain 130 and be separated from the source 120. That is, the shielding layer 140 can be integrated with the drain 130 and therefore serve as a portion of the drain 130.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A thin film transistor, comprising a gate, a source, a drain, a channel layer, and a shielding layer, wherein the shielding layer, the source, and the drain are located on the channel layer, and the shielding layer is located between the source and the drain and is separated from the source and the drain.

2. The thin film transistor according to claim 1, wherein the shielding layer is made of the same materials with the source and the drain.

3. The thin film transistor according to claim 2, wherein the shielding layer, the source, and the drain are formed in a same photo etching process.

4. The thin film transistor according to claim 1, wherein the a total distance of a first distance between the source and the shielding layer and a second distance between the drain and the shielding layer is less than a half of a distance between the source and the drain.

5. The thin film transistor according to claim 4, wherein the first distance between the source and the shielding layer is identical to the second distance between the drain and the shielding layer.

6. The thin film transistor according to claim 1, wherein the channel layer is made of materials having light sensitivity performance.

7. The thin film transistor according to claim 6, wherein the channel layer is made of metal oxide materials.

8. The thin film transistor according to claim 1, further comprising an etching stopping layer located on a surface of the channel layer to separate the source from drain.

9. The thin film transistor according to claim 8, wherein the etching stopping layer defines two contact holes to expose a portion of the channel layer, the source and the drain are respectively contacted with the channel layer via the two contact holes.

10. The thin film transistor according to claim 8, wherein the etching stopping layer is shorter than the channel layer, the channel layer is exposed out from two opposite sides of the etching stopping layer, and the source and the drain are respectively located at the two opposite sides of the etching stopping layer to contact with the channel layer.

11. A thin film transistor, comprising a gate, a source, a drain, a channel layer, and a shielding layer, wherein the shielding layer, the source, and the drain are located on the channel layer, and the shielding layer is coupled to one of the source and the drain and is separate from the other of the source and the drain, a length of the shielding layer is less than a distance between the source and the drain but is greater than a half of the distance between the source and the drain.

12. The thin film transistor according to claim 11, wherein the shielding layer is made of the same materials with the source and the drain in a same photo etching process.

13. The thin film transistor according to claim 11, wherein the shielding layer is integrated with one of the source and the drain and serve as a portion of one of the source and the drain.

14. The thin film transistor according to claim 11, wherein the shield layer comprises an irregular structure having at least one concave portion and at least one protrusion portion located at one side of the shielding layer adjacent to one of the source and drain which is separated from the shield layer.

15. The thin film transistor according to claim 11, wherein the channel layer is made of materials having light sensitivity performance.

16. The thin film transistor according to claim 15, wherein the channel layer is made of metal oxide materials.

17. An array substrate of a display panel, comprising:
a plurality of gate lines and a plurality of data lines intersected with and insulated from the gate lines to form a plurality of pixel units, each pixel unit comprising at least one thin film transistor, the thin film transistor comprising:
a gate, a source, a drain, a channel layer, and a shielding layer located on the channel layer;
wherein the shielding layer, the source, and the drain are located on a same layer, and the shielding layer is located between the source and the drain and is separated from the source and the drain.

18. The array substrate according to claim 17, wherein the shielding layer is made of the same materials with the source and the drain in a same photo etching process.

19. The array substrate according to claim 17, wherein the a total distance of a first distance between the source and the shielding layer and a second distance between the drain and the shielding layer is less than a half of a distance between the source and the drain.

20. The array substrate according to claim 17, wherein the channel layer is made of materials having light sensitivity performance.
